(19) United States
(12) Patent Application Publication
(10) Pub. No.: US 2025/0192124 A1
(43) Pub. Date: Jun. 12, 2025

(54) DISPLAY DEVICE

(71) Applicant: Samsung Display Co., LTD., Yongin-si (KR)

(72) Inventors: RAN KIM, Yongin-si (KR); KIHYUN KIM, Yongin-si (KR); SUNGHWAN YOUN, Yongin-si (KR)

(21) Appl. No.: 18/827,552

(22) Filed: Sep. 6, 2024

(30) Foreign Application Priority Data
Dec. 11, 2023 (KR) 10-2023-0178404

(51) Int. Cl. H01L 25/16; H01L 33/62

(52) U.S. Cl. CPC H01L 25/167; H10H 20/857

(57) ABSTRACT

A display device includes: a base substrate; a transistor on the base substrate and comprising a semiconductor pattern and a gate electrode; a gate insulating pattern layer on the semiconductor pattern; connection electrodes on the gate insulating pattern layer and connected to the semiconductor pattern via contact holes; and an insulating layer on the connection electrodes and the transistor, wherein the connection electrodes are on a same layer as the gate electrode, the insulating layer comprises a low transmittance layer having a light transmittance equal to or greater than 30% and equal to or smaller than 65%.

### CROSS-REFERENCE TO RELATED APPLICATION(S)

The present application claims priority to and the benefit of Korean Patent Application No. 10-2023-0178404, filed on Dec. 11, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

Multimedia display devices, such as televisions, mobile phones, tablet computers, computers, navigation units, and game units, include a display panel to display images. The display panel includes pixels configured to display images, and each of the pixels includes a light emitting element emitting a light and a driving element connected to the light emitting element.

The light emitting element and the driving element of the display panel may be formed by stacking thin layers and pattering the thin layers using a mask. Because a display panel manufacturing process using a mask incurs a lot of costs, it may be desirable to reduce the number of masks used to manufacture a display device by simplifying the display panel manufacturing process. In addition, it may be desirable to manufacture the display panel with reliability while relatively simplifying the manufacturing process.

The above information disclosed in this Background section is only for enhancement of understanding of the background and therefore the information discussed in this Background section does not necessarily constitute prior art.

### SUMMARY

Aspects of some embodiments of the present disclosure relate to a display device. For example, aspects of some embodiments of the present disclosure relate to a display device with relatively improved reliability.

Aspects of some embodiments of the present disclosure include a display device with a relatively simplified manufacturing process and a relatively improved display quality.

According to some embodiments of the present disclosure, a display device includes a base substrate, a transistor on the base substrate and including a semiconductor pattern and a gate electrode, a gate insulating pattern layer on the semiconductor pattern, connection electrodes on the gate insulating pattern layer and connected to the semiconductor pattern via contact holes, and an insulating layer on the connection electrodes and the transistor. According to some embodiments, the connection electrodes are on the same layer as the gate electrode, the insulating layer includes a low transmittance layer having a light transmittance equal to or greater than about 30% and equal to or smaller than about 65%.

According to some embodiments, the low transmittance layer includes silicon atoms and nitrogen atoms, and a proportion of the silicon atoms of the low transmittance layer is greater than a proportion of the nitrogen atoms of the low transmittance layer.

According to some embodiments, the proportion of the silicon atoms of the low transmittance layer is equal to or greater than about 55% and equal to or smaller than about 70%, and the proportion of the nitrogen atoms of the low transmittance layer is equal to or greater than about 30% and equal to or smaller than about 45%.

According to some embodiments, the low transmittance layer has a thickness equal to or greater than about 1500 angstroms and equal to or smaller than about 3000 angstroms.

According to some embodiments, the insulating layer further includes a first high transmittance layer on the low transmittance layer, and the first high transmittance layer has a light transmittance equal to or greater than about 80% and equal to or smaller than about 95%.

According to some embodiments, the first high transmittance layer includes silicon atoms and nitrogen atoms, and a proportion of the nitrogen atoms of the first high transmittance layer is greater than a proportion of the silicon atoms of the first high transmittance layer.

According to some embodiments, the insulating layer further includes a second high transmittance layer under the low transmittance layer, and the second high transmittance layer has a light transmittance equal to or greater than about 80% and equal to or smaller than about 95%.

According to some embodiments, the insulating layer further includes a stabilizing layer under the second high transmittance layer, the stabilizing layer includes silicon atoms, nitrogen atoms, and oxygen atoms, and a proportion of the oxygen atoms of the stabilizing layer is greater than each of a proportion of the silicon atoms of the stabilizing layer and a proportion of the nitrogen atoms of the stabilizing layer.

According to some embodiments, the insulating layer further includes a third high transmittance layer between the second high transmittance layer and the stabilizing layer, and the third high transmittance layer has a light transmittance equal to or greater than about 80% and equal to or smaller than about 95%.

According to some embodiments, the insulating layer has a thickness equal to or greater than about 2500 angstroms and equal to or smaller than about 5000 angstroms.

According to some embodiments, the semiconductor pattern includes a source area, a drain area, and an active area, the connection electrodes include a first connection electrode connected to the drain area and a second connection electrode connected to the source area, and the first connection electrode and the second connection electrode are on the same layer as the gate electrode.

According to some embodiments, the first connection electrode and the second connection electrode include the same material as the gate electrode.

According to some embodiments, the display device further includes first and second conductive patterns between the base substrate and the transistor and spaced apart from each other when viewed in a plane (or in a plan view). According to some embodiments, the first conductive pattern is electrically connected to the drain area through the first connection electrode, and the second conductive pattern is electrically connected to the source area through the second connection electrode.

According to some embodiments, the gate insulating pattern layer includes first, second, and third insulating patterns, the first insulating pattern overlaps the first connection electrode, the second insulating pattern overlaps the gate electrode, and the third insulating pattern overlaps the second connection electrode.

According to some embodiments, the first connection electrode is connected to the first conductive pattern via a first contact hole defined through the first insulating pattern, and the second connection electrode is connected to the second conductive pattern via a second contact hole defined through the third insulating pattern.

According to some embodiments, the display device further includes a light emitting element on the first and second connection electrodes and including a first electrode, a light emitting layer, and a second electrode. According to some embodiments, the first electrode is electrically connected to the transistor through the first connection electrode.

According to some embodiments of the present disclosure, a display device includes a base substrate, a transistor on the base substrate and including a semiconductor pattern and a gate electrode, a gate insulating pattern layer on the semiconductor pattern, connection electrodes on the gate insulating pattern layer and connected to the semiconductor pattern via contact holes, and an insulating layer on the connection electrodes and the transistor. According to some embodiments, the insulating layer includes a low transmittance layer having a first light transmittance and a high transmittance layer having a second light transmittance greater than the first light transmittance and on or under the low transmittance layer.

According to some embodiments, the first light transmittance is equal to or greater than about 30% and equal to or smaller than about 65%, and the second light transmittance is equal to or greater than about 80% and equal to or smaller than about 95%.

According to some embodiments, the high transmittance layer includes a first high transmittance layer on the low transmittance layer and a second high transmittance layer under the low transmittance layer, and each of the first and second high transmittance layers has the second light transmittance.

According to some embodiments, the insulating layer further includes a third high transmittance layer under the second high transmittance layer and a stabilizing layer under the third high transmittance layer.

According to some embodiments, the insulating layer has a thickness equal to or greater than about 2500 angstroms and equal to or smaller than about 5000 angstroms.

According to some embodiments, the low transmittance layer includes silicon atoms and nitrogen atoms, and a proportion of the silicon atoms of the low transmittance layer is greater than a proportion of the nitrogen atoms of the low transmittance layer.

According to some embodiments, the proportion of the silicon atoms of the low transmittance layer is equal to or greater than about 55% and equal to or smaller than about 70%, and the proportion of the nitrogen atoms of the low transmittance layer is equal to or greater than about 30% and equal to or smaller than about 45%.

According to some embodiments, the low transmittance layer has a thickness equal to or greater than about 1500 angstroms and equal to or smaller than about 3000 angstroms.

According to some embodiments of the present disclosure, the display device includes the low transmittance layer and also includes the insulating layer located on the connection electrodes and the transistor. According to some embodiments, the light transmittance of the low transmittance layer may be set to be equal to or greater than about 30% and equal to or smaller than about 65%. In addition, the number of dangling bonds included in the low transmittance layer is set to be equal to or smaller than about 5×10¹⁸ spins/cm³. Accordingly, the deterioration of the transistor due to external light may be relatively reduced by the low transmittance layer, a charge trap does not occur in the insulating layer, and the image retention appeared when a display panel is in operation is not visible from the outside.

### BRIEF DESCRIPTION OF THE DRAWINGS

The above and other aspects of embodiments according to the present disclosure will become readily apparent by reference to the following detailed description when considered in conjunction with the accompanying drawings wherein:

FIG. 1 is a perspective view of a display device according to some embodiments of the present disclosure;

FIG. 2A is an exploded perspective view of a display device according to some embodiments of the present disclosure;

FIG. 2B is a cross-sectional view of a display module according to some embodiments of the present disclosure;

FIG. 3 is a plan view of a display panel according to some embodiments of the present disclosure;

FIG. 4 is a cross-sectional view taken along a line I-I′ of FIG. 3;

FIGS. 5A and 5B are plan views corresponding to a circuit layer shown in FIG. 4;

FIG. 6 is an enlarged view of an area AA′ shown in FIG. 4;

FIG. 7A is a graph illustrating a relationship between a content of nitrogen atoms contained in a specific material and a light transmittance of the specific material;

FIG. 7B is a graph illustrating a relationship between a light transmittance of a specific material and the number of dangling bonds included in the specific material;

FIGS. 8A to 8D are enlarged views of a portion of a display panel according to some embodiments of the present disclosure; and

FIG. 9 is a cross-sectional view of a display panel according to some embodiments of the present disclosure.

### DETAILED DESCRIPTION

The present disclosure may be variously modified and realized in many different forms, and thus aspects of some embodiments will be illustrated in the drawings and described in more detail hereinbelow. However, embodiments of the present disclosure are not limited to the specific disclosed forms, and should be construed to include all modifications, equivalents, or replacements included in the spirit and scope of embodiments according to the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, aspects of some embodiments of the present disclosure will be described in more detail with reference to accompanying drawings.

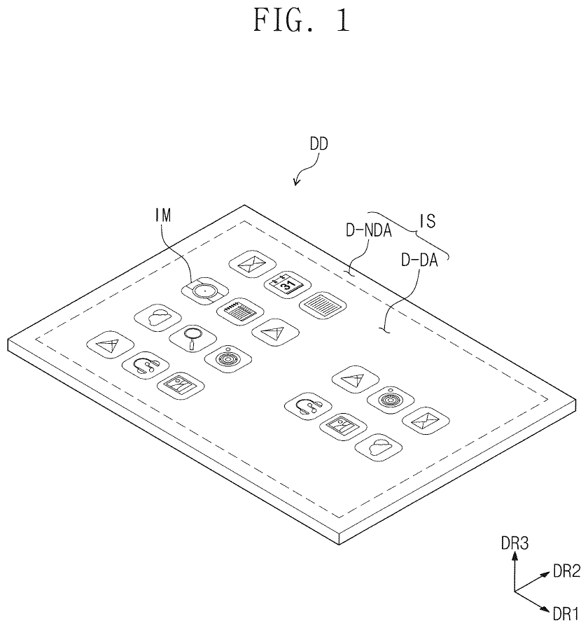

FIG. 1 is a perspective view of a display device DD according to some embodiments of the present disclosure.

Referring to FIG. 1, the display device DD may be activated in response to electrical signals and may display an image IM. The display device DD may include various embodiments to provide the image IM to a user. As an example, the display device DD may be applied to a large-sized electronic device, such as a television set, an outdoor billboard, etc., and a small and medium-sized electronic device, such as a monitor, a mobile phone, a tablet computer, a navigation unit, a game unit, etc. However, these are merely examples, and the display device DD may be applied to other electronic devices as long as they do not depart from the concept of the present disclosure.

The display device DD may have a generally rectangular shape with long sides extending in a first direction DR1 and short sides extending in a second direction DR2 crossing the first direction DR1. However, the shape of the display device DD should not be limited to the rectangular shape, and the display device DD may have a variety of shapes, such as a circular shape, a polygonal shape, etc.

The display device DD may display the image IM through a display surface IS toward a third direction DR3, which is perpendicular to a plane defined by the first direction DR1 and the second direction DR2. A normal line direction of the display surface IS may be parallel to the third direction DR3. The display surface IS through which the image IM is displayed may correspond to a front surface of the display device DD. The image IM may include a still image as well as a video. FIG. 1 shows application icons as a representative example of the image IM.

In the present embodiments, front (or upper) and rear (or lower) surfaces of each member of the display device DD may be defined with respect to the third direction DR3. The front and rear surfaces are opposite to each other along the third direction DR3, and a normal line direction of each of the front and rear surfaces may be parallel to the third direction DR3. A separation distance between the front and rear surfaces of each member in the third direction DR3 may correspond to a thickness of the member in the third direction DR3.

In the present disclosure, the expressions “when viewed in a plane” or “in a plan view” may mean a state of being viewed from or along the third direction DR3. In the present disclosure, the expression “when viewed in a cross-section” may mean a state of being viewed in the first direction DR1 or the second direction DR2. Meanwhile, directions indicated by the first, second, and third directions DR1, DR2, and DR3 are relative to each other, and thus, the directions indicated by the first, second, and third directions DR1, DR2, and DR3 may be changed to other directions.

FIG. 1 shows the display device DD including the display surface IS that is flat as a representative example. However, the shape of the display surface IS of the display device DD should not be limited thereto or thereby, and the display surface IS may have a curved or three-dimensional shape.

The display device DD may be flexible. The term “flexible” used herein refers to the property of being able to be bent, from a structure that is completely bent to a structure that is bent at the scale of a few nanometers. For example, the display device DD may be a curved display device or a foldable display device, however, embodiments according to the present disclosure are not limited thereto or thereby. According to some embodiments, the display device DD may be rigid.

The display surface IS of the display device DD may include a display part D-DA and a non-display part D-NDA. The display part D-DA may be a part where the image IM is displayed within the front surface of the display device DD, and a user may view the image IM through the display part D-DA. According to some embodiments, the display part D-DA having a quadrangular shape in a plane (or in a plan view) is illustrated as a representative example, however, the display part D-DA may have a variety of shapes depending on a design of the display device DD.

The non-display part D-NDA may be a part where the image IM is not displayed within the front surface of the display device DD. The non-display part D-NDA may have a color (e.g., a set or predetermined color) and may block a light. The non-display part D-NDA may be located adjacent to the display part D-DA. As an example, the non-display part D-NDA may be located outside of the display part D-DA and may surround the display part D-DA, however, this is merely an example. The non-display part D-NDA may be defined adjacent to only one side of the display part D-DA or may be defined in a side surface rather than the front surface of the display device DD. According to some embodiments, the non-display part D-NDA may be omitted.

According to some embodiments, the display device DD may sense an external input applied thereto from the outside. The external input may include a variety of external inputs provided from the outside, such as pressure, heat, light, etc. The external input may include a proximity input (e.g., a hovering input) applied when approaching close to or adjacent to the display device DD at a distance (e.g., a set or predetermined distance) as well as a touch input, e.g., a touch by a hand of a user or a pen.

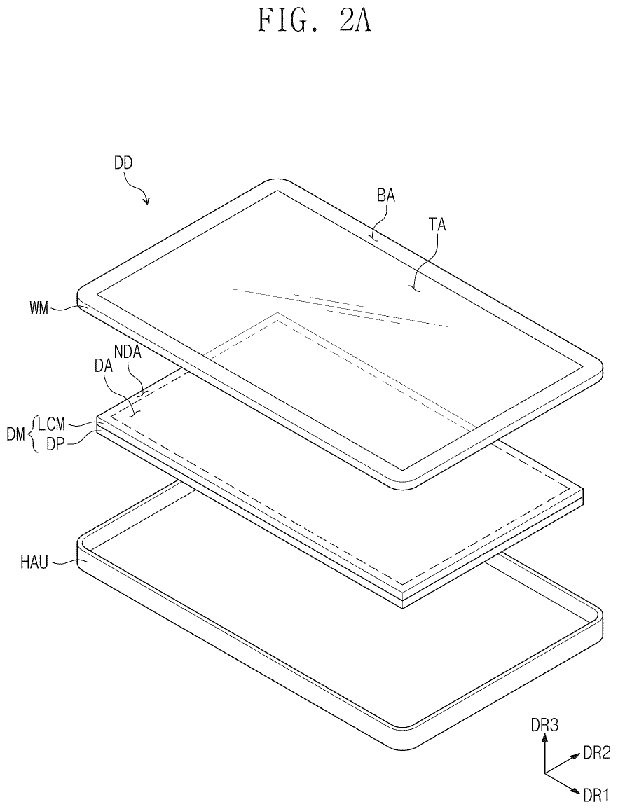

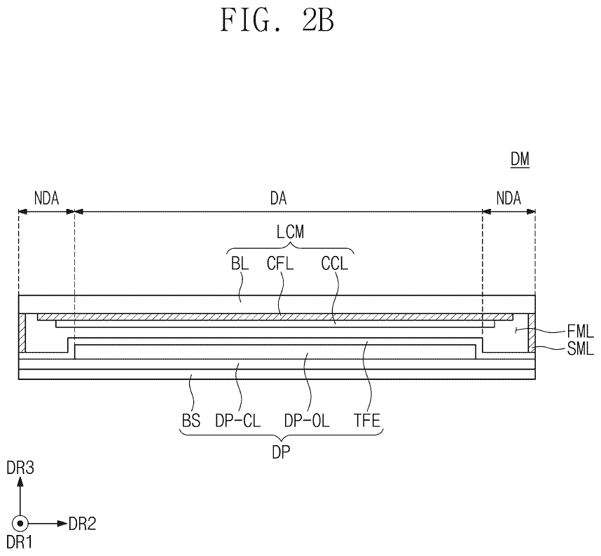

FIG. 2A is an exploded perspective view of the display device DD according to some embodiments of the present disclosure. FIG. 2B is a cross-sectional view of a display module DM according to some embodiments of the present disclosure.

Referring to FIGS. 2A and 2B, the display device DD may include a window WM, the display module DM, and a housing HAU. The display module DM may include a display panel DP and a light control member LCM located on the display panel DP.

The window WM may be coupled with the housing HAU to form an external appearance of the display device DD and to provide an inner space in which components, e.g., the display module DM, of the display device DD are accommodated.

The window WM may be located on the display module DM. The window WM may protect the display module DM from external impacts, and prevent components of the display device DD being damaged. A front surface of the window WM may correspond to the display surface IS of the display device DD. The front surface of the window WM may include a transmission area TA and a bezel area BA.

The transmission area TA of the window WM may be an optically transparent area. The window WM may transmit the image provided from the display module DM through the transmission area TA, and the user may view the image. The transmission area TA of the window WM may correspond to the display part D-DA of the display device DD.

The window WM may include an optically transparent insulating material. As an example, the window WM may include a glass, sapphire, or plastic material. The window WM may have a single-layer or multi-layer structure. The window WM may further include functional layers, such as an anti-fingerprint layer, a phase control layer, a hard coating layer, etc., located on an optically transparent substrate.

The bezel area BA of the window WM may be obtained by depositing, coating, or printing a material having a color (e.g., a set or predetermined color) on a transparent substrate. The bezel area BA of the window WM may prevent or reduce visibility of components of the display module DM, which are arranged to overlap the bezel area BA, from the outside. The bezel area BA may correspond to the non-display part D-NDA of the display device DD.

The display module DM may be located between the window WM and the housing HAU. The display module DM may display the image in response to electrical signals. The display module DM may include a display area DA and a non-display area NDA defined adjacent to (e.g., in a periphery or outside a footprint of) the display area DA.

The display area DA may be activated in response to electrical signals and may display the image. The display area DA of the display module DM may overlap the transmission area TA of the window WM. In the present disclosure, the expression “An area/portion overlaps another area/portion.” should not be limited to meaning that “An area/portion has the same size and/or the same shape as those of another area/portion.” The image provided from the display area DA may be viewed from the outside through the transmission area TA.

The non-display area NDA may be defined adjacent to the display area DA. As an example, the non-display area NDA may surround the display area DA, however, it should not be limited thereto or thereby. According to some embodiments, the non-display area NDA may be defined in a variety of shapes. A driving circuit or a driving line to drive elements located in the display area DA, various signal lines to provide electrical signals to the elements, and pads may be located in the non-display area NDA. The non-display area NDA of the display module DM may overlap the bezel area BA of the window WM, and visibility of components of the display module DM, which are located in the non-display area NDA, from the outside by the bezel area BA may be prevented or reduced.

The display panel DP according to some embodiments may be a light-emitting type display panel, however, it should not be particularly limited. For instance, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, the organic light emitting display panel will be described as a representative example of the display panel DP.

The display panel DP may include a base substrate BS, a circuit layer DP-CL, a display element layer DP-OL, and an encapsulation layer TFE.

The base substrate BS may provide a base surface on which the circuit layer DP-CL is located. The base substrate BS may be a rigid substrate or a flexible substrate.

The circuit layer DP-CL may be located on the base substrate BS. The circuit layer DP-CL may include driving elements such as transistors, signal lines, and signal pads. The display element layer DP-OL may include light emitting elements arranged to overlap the display area DA. The light emitting elements of the display element layer DP-OL may be electrically connected to the driving elements of the circuit layer DP-CL and may emit a light through the display area DA in response to a signal from the driving element.

The encapsulation layer TFE may be located on the display element layer DP-OL and may encapsulate the light emitting elements. The encapsulation layer TFE may include a plurality of thin layers. The thin layers of the encapsulation layer TFE may improve an optical efficiency of the light emitting elements or may protect the light emitting elements.

The light control member LCM may be located on the display panel DP. The light control member LCM may be coupled to the display panel DP by a coupling process using a sealing member SML after being provided on the display panel DP.

However, according to some embodiments, the light control member LCM may be located directly on the display panel DP. In the present disclosure, a structure in which one layer, component, member, or the like is formed on another layer, component, member, or the like through successive processes without using a separate adhesive layer or adhesive member will be referred to as “being directly located”. As an example, the expression “The light control member LCM is located directly on the display panel DP.” means that the light control member LCM is formed on a base surface of the display panel DP through successive processes without employing a separate adhesive layer after the display panel DP is formed.

The light control member LCM may selectively convert a wavelength of a light, i.e., a source light, provided from the display panel DP or may selectively transmit the source light. As an example, the light control member LCM may include light conversion patterns that convert an optical property of the source light provided from the display panel DP. The light control member LCM may control a color purity or a color reproducibility of the light exiting from the display device DD and may prevent or reduce reflection of an external light incident thereinto from the outside of the display device DD.

The light control member LCM may include a base layer BL, a color filter layer CFL, and a light control layer CCL. The base layer BL may be arranged to face the base substrate BS of the display panel DP, and the color filter layer CFL and the light control layer CCL, which are located on the base layer BL, may be located between the display panel DP and the base layer BL.

The light control layer CCL may include a quantum dot that converts a wavelength of the source light provided from the display panel DP or may further include a transmission portion that transmits the source light. The source light passing through the quantum dot included in the light control layer CCL may be emitted as a color light with a color different from that of the source light.

The color filter layer CFL may include color filters, and the color filters may transmit or absorb lights passing through the light control layer CCL according to their colors. The color filter layer CFL may absorb lights that are not converted by the light control layer CCL and thus may prevent or reduce lowering of a color purity of the display device DD. In addition, the color filter layer CFL may filter the external light to have the same color as that provided by pixels and may relatively reduce the reflection of the external light.

The sealing member SML may be located in the non-display area NDA that is an outer area of the display module DM and may prevent or reduce instances of a contaminant or a foreign substance, such as oxygen or moisture, entering the display module DM from the outside of the display module DM. The sealing member SML may be formed of a sealant containing a curable resin.

The display module DM may further include a filling layer FML located between the display panel DP and the light control member LCM. The filling layer FML may be filled in a space between the display panel DP and the light control member LCM. The filling layer FML may function as a buffer between the display panel DP and the light control member LCM. According to some embodiments, the filling layer FML may absorb an impact and may increase a strength of the display module DM.

The filling layer FML may be formed of a filling resin including a polymer resin. As an example, the filling layer FML may include an acrylic-based resin or an epoxy-based resin. However, according to some embodiments, the light control member LCM may be located directly on the display panel DP, and the filling layer FML and the sealing member SML may be omitted. In the case where the light control member LCM is located directly on the display panel DP, the base layer BL of the light control member LCM may be omitted.

The housing HAU may be located under the display module DM and may accommodate the display module DM. The housing HAU may absorb impacts applied to the display module DM from the outside (thereby preventing or reducing damage to the internal components of the display device DD) and may prevent or reduce instances of contaminants or a foreign substance, such as moisture, entering the display module DM, and thus, the display module DM may be protected by the housing HAU. According to some embodiments, the housing HAU may be provided in a form obtained by coupling a plurality of accommodating members.

Meanwhile, the display device DD may further include an input sensing module. The input sensing module may obtain coordinate information of the external input applied thereto from the outside of the display device DD. The input sensing module of the display device DD may be driven in various ways, such as a capacitive method, a resistive method, an infrared ray method, a pressure method, or the like, and it should not be particularly limited.

The input sensing module may be located on the display module DM. The input sensing module may be located directly on the display module DM through successive processes or may be attached to the display module DM by an adhesive layer after being manufactured separately from the display module DM, however, the present disclosure should not be limited thereto or thereby. According to some embodiments, the input sensing module may be located between components of the display module DM. As an example, the input sensing module may be located between the display panel DP and the light control member LCM.

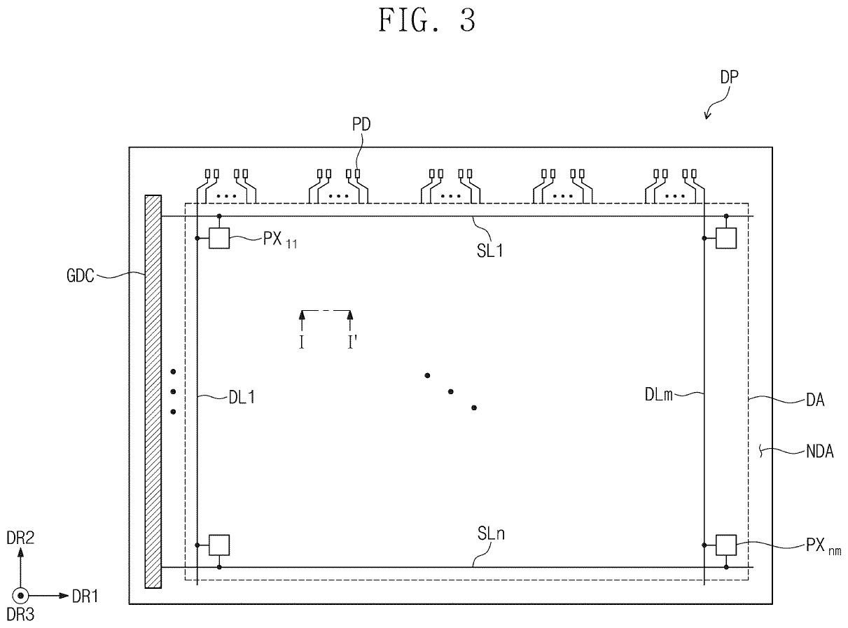

FIG. 3 is a plan view of the display panel DP according to some embodiments of the present disclosure.

Referring to FIG. 3, the display panel DP may include pixels PX11 to PXnm located in the display area DA and signal lines SL1 to SLn and DL1 to DLm electrically connected to the pixels PX11 to PXnm. The display panel DP may include a driving circuit GDC and pads PD, which are located in the non-display area NDA.

Each of the pixels PX11 to PXnm may include a pixel driving circuit configured to include the light emitting element, a plurality of transistors, e.g., a switching transistor, a driving transistor, etc., connected to the light emitting element, and a capacitor. Each of the pixels PX11 to PXnm may emit a light in response to an electrical signal applied thereto. FIG. 3 shows the pixels PX11 to PXnm arranged in a matrix form as a representative example, however, the arrangement of the pixels PX11 to PXnm should not be limited thereto or thereby.

The signal lines SL1 to SLn and DL1 to DLm may include scan lines SL1 to SLn and data lines DL1 to DLm. Each of the pixels PX11 to PXnm may be connected to a corresponding scan line of the scan lines SL1 to SLn and a corresponding data line of the data lines DL1 to DLm. Meanwhile, more types of signal lines may be provided in the display panel DP depending on the configuration of the pixel driving circuit of the pixels PX11 to PXnm.

The driving circuit GDC may include a gate driving circuit. The gate driving circuit may generate gate signals and may sequentially output the gate signals to the scan lines SL1 to SLn. The gate driving circuit may further output another control signal to the pixel driving circuit of the pixels PX11 to PXnm.

The driving circuit GDC and the pixels PX11 to PXnm may include a plurality of transistors formed through a process, for instance, a low temperature polycrystalline silicon (LTPS) process, a low temperature polycrystalline oxide (LTPO) process, or an oxide semiconductor process.

The pads PD may be arranged in the non-display area NDA along one direction. The pads PD may be connected to a circuit board. Each of the pads PD may be connected to a corresponding signal line among the signal lines SL1 to SLn and DL1 to DLm and may be connected to corresponding pixels among the pixels PX11 to PXnm via the signal line. The pads PD may be provided integrally with the signal lines SL1 to SLn and DL1 to DLm, however, they should not be limited thereto or thereby. According to some embodiments, the pads PD may be located on a different layer from the signal lines SL1 to SLn and DL1 to DLm and may be connected to the signal lines SL1 to SLn and DL1 to DLm via a contact hole.

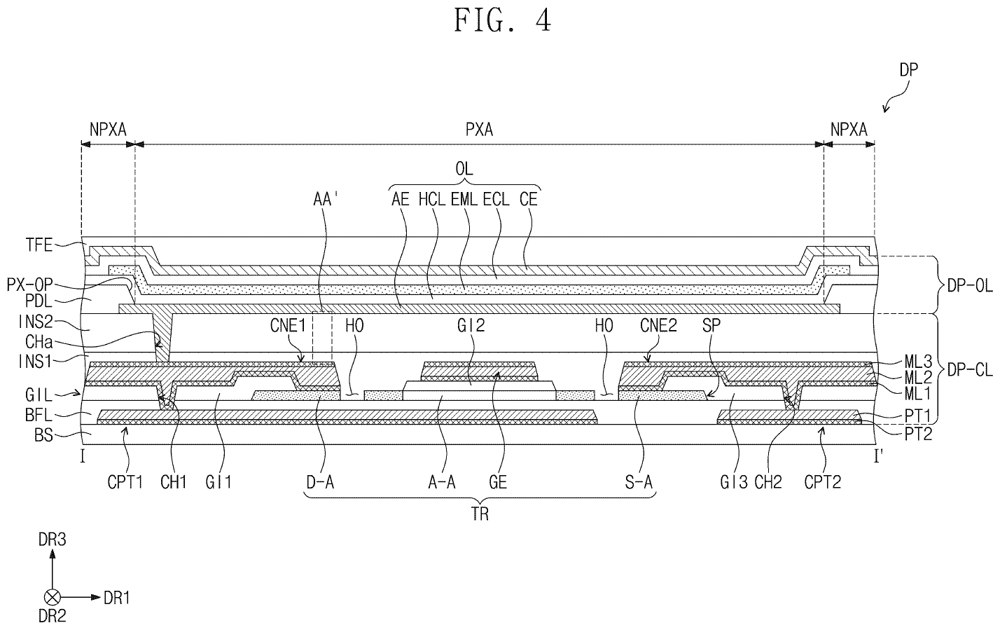

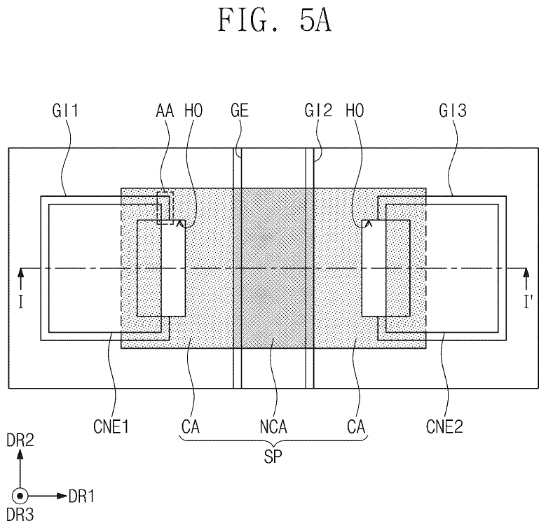

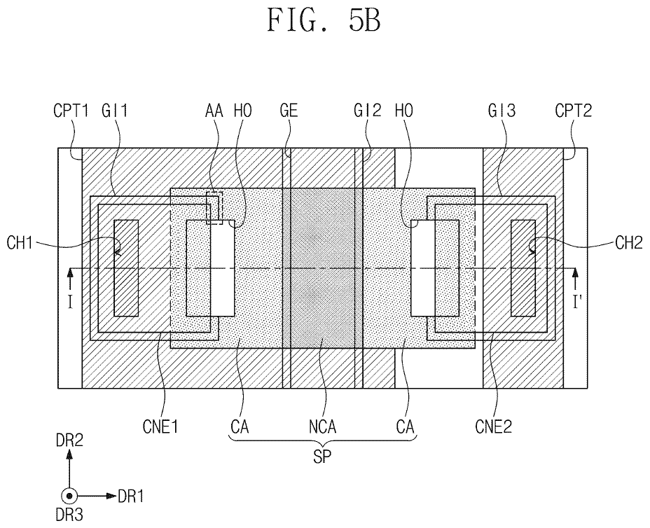

FIG. 4 is a cross-sectional view taken along a line I-I′ of FIG. 3. FIGS. 5A and 5B are plan views corresponding to a circuit layer shown in FIG. 4. In detail, FIG. 5A is a plan view illustrating connection electrodes CNE1 and CNE2 and a transistor TR, and FIG. 5B is a plan view illustrating first and second conductive patterns CPT1 and CPT2 in addition to the connection electrodes CNE1 and CNE2 and the transistor TR of FIG. 5A. Hereinafter, the display panel DP will be described with reference to FIGS. 4, 5A, and 5B.

Referring to FIG. 4, the display panel DP may include the base substrate BS, the circuit layer DP-CL, the display element layer DP-OL, and the encapsulation layer TFE.

The circuit layer DP-CL may include the conductive patterns CPT1 and CPT2, the transistor TR, the connection electrodes CNE1 and CNE2, a buffer layer BFL, a gate insulating pattern layer GIL, and insulating layers INS1 and INS2, which are located on the base substrate BS.

Each of the first conductive pattern CPT1 and the second conductive pattern CPT2 may have a multi-layer structure. The first conductive pattern CPT1 and the second conductive pattern CPT2 may be formed of the same material and may have the same stack structure. As an example, each of the first conductive pattern CPT1 and the second conductive pattern CPT2 may include a first pattern layer PT1 and a second pattern layer PT2, which are stacked on the base substrate BS along a thickness direction, however, embodiments according to the present disclosure are not limited thereto or thereby. According to some embodiments, each of first and second conductive patterns CPT1 and CPT2 may have a single-layer structure or may have a multi-layer structure in which the number of stacked pattern layers is greater than the number of pattern layers shown in FIG. 4.

The first pattern layer PT1 and the second pattern layer PT2 may have different thicknesses from each other. As an example, the thickness of the first pattern layer PT1 may be smaller than the thickness of the second pattern layer PT2, however, embodiments according to the present disclosure are not limited thereto or thereby.

Each of the first pattern layer PT1 and the second pattern layer PT2 may include one of molybdenum (Mo), aluminum (AI), chromium (Cr), gold (Au), titanium (Ti), nickel (Ni), neodymium (Nd), and copper (Cu) or an alloy thereof. As an example, the first pattern layer PT1 may include titanium (Ti), and the second pattern layer PT2 may include copper (Cu), however, embodiments according to the present disclosure are not limited thereto or thereby.

The buffer layer BFL may be located on the base substrate BS to cover the first and second conductive patterns CPT1 and CPT2. The buffer layer BFL may include at least one inorganic layer.

Referring to FIGS. 4 and 5A, the transistor TR may include a semiconductor pattern SP and a gate electrode GE. The semiconductor pattern SP may be located on the buffer layer BFL. An adhesion between the semiconductor pattern SP and the base substrate BS may be relatively improved by the buffer layer BFL. The semiconductor pattern SP may include a semiconductor material, such as polycrystalline silicon, crystalline silicon, or metal oxide.

A source area S-A, an active area A-A, and a drain area D-A of the transistor TR may be formed from the semiconductor pattern SP. The semiconductor pattern SP may have different electrical properties depending on whether it is doped or not or whether a metal oxide is reduced or not. The source area S-A and the drain area D-A of the semiconductor pattern SP, which have a relatively high conductivity, may serve as an electrode or a signal line. A non-doped portion, a portion doped with a low doping concentration, or a non-reduced portion of the semiconductor pattern SP may correspond to the active area A-A with a relatively low conductivity.

Conductive areas CA may be spaced apart from each other with a non-conductive area NCA interposed therebetween. The conductive areas CA may correspond to the source area S-A and the drain area D-A of the semiconductor pattern SP, and the non-conductive area NCA may correspond to a channel area of the semiconductor pattern SP.

At least one hole HO may be defined through the semiconductor pattern SP. The hole HO may be formed during an etching process of forming the connection electrodes CNE1 and CNE2 and the gate electrode GE. FIG. 4 shows a structure in which the holes HO are formed through the semiconductor pattern SP and spaced apart from each other as a representative example. Among the holes HO, one hole HO may be surrounded by the source area S-A when viewed in the plane (or in a plan view), and the other hole HO may be surrounded by the drain area D-A, however, the present disclosure should not be limited thereto or thereby. According to some embodiments, the hole HO may not be formed through the semiconductor pattern SP depending on the process of forming the circuit layer DP-CL.

The gate insulating pattern layer GIL may be located on the buffer layer BFL. The gate insulating pattern layer GIL may include at least one inorganic layer.

The gate insulating pattern layer GIL may include first, second, and third insulating patterns GI1, GI2, and GI3 spaced apart from each other. The first insulating pattern Gl1 may cover a portion of the drain area D-A and may be located above the first conductive pattern CPT1. The second insulating pattern GI2 may be located in the active area A-A. The third insulating pattern GI3 may cover a portion of the source area S-A and may be located above the second conductive pattern CPT2.

Referring to FIGS. 4 and 5B, the connection electrodes CNE1 and CNE2 may include a first connection electrode CNE1 and a second connection electrode CNE2. The first connection electrode CNE1 may be located on the first insulating pattern Gl1. The first connection electrode CNE1 may be connected to the first conductive pattern CPT1 via a first contact hole CH1 defined through the buffer layer BFL and the first insulating pattern Gl1. The first connection electrode CNE1 may be in contact with a portion of the drain area D-A and may be connected to the drain area D-A. The drain area D-A and the first conductive pattern CPT1 may be electrically connected to each other by the first connection electrode CNE1. As the first conductive pattern CPT1 with high conductivity is connected to the drain area D-A, current transfer characteristics may be improved.

The second connection electrode CNE2 may be located on the third insulating pattern GI3. The second connection electrode CNE2 may be connected to the second conductive pattern CPT2 via a second contact hole CH2 defined through the buffer layer BFL and the third insulating pattern GI3. The second connection electrode CNE2 may be in contact with a portion of the source area S-A and may be connected to the source area S-A. The source area S-A and the second conductive pattern CPT2 may be electrically connected to each other by the second connection electrode CNE2. The second connection electrode CNE2 may be connected to a power line that supplies a power to a light emitting element OL, and thus, may supply a first voltage to the transistor TR.

The gate electrode GE may be located on the second insulating pattern GI2. The gate electrode GE may overlap the active area A-A when viewed in the plane (or in a plan view) and may be spaced apart from the semiconductor pattern SP with the second insulating pattern GI2 interposed therebetween in the thickness direction.

The connection electrodes CNE1 and CNE2 may be spaced apart from the gate electrode GE when viewed in the plane (or in a plan view). The connection electrodes CNE1 and CNE2 and the gate electrode GE may have a multi-layer structure in which conductive layers ML1, ML2, and ML3 including different materials from each other are stacked. The conductive layers ML1, ML2, and ML3 may include first, second, and third conductive layers ML1, ML2, and ML3. The first, second, and third conductive layers ML1, ML2, and ML3 may be stacked through a sputtering process, however, the present disclosure should not be limited thereto or thereby.

Each of the first, second, and third conductive layers ML1, ML2, and ML3 may include a metal material. As an example, each of the first, second, and third conductive layers ML1, ML2, and ML3 may include one of molybdenum (Mo), aluminum (AI), chromium (Cr), gold (Au), titanium (Ti), nickel (Ni), neodymium (Nd), copper (Cu), and indium tin oxide (ITO) or an alloy thereof. The first, second, and third conductive layers ML1, ML2, and ML3 may include different metal materials from each other. The second conductive layer ML2 may include a metal material with high conductivity, and the first and third conductive layers ML1 and ML3 respectively located under and on the second conductive layer ML2 may include a metal material with a corrosion resistance. As an example, the first conductive layer ML1 may include titanium (Ti), the second conductive layer ML2 may include copper (Cu), and the third conductive layer ML3 may include indium tin oxide (ITO), however, the present disclosure should not be limited thereto or thereby.

The first, second, and third conductive layers ML1, ML2, and ML3 may have different thicknesses from each other. As an example, the second conductive layer ML2 including the metal material with high conductivity may have the largest thickness among the first, second, and third conductive layers ML1, ML2, and ML3. Therefore, the connection electrodes CNE1 and CNE2 and the gate electrode GE, which are formed from the first, second, and third conductive layers ML1, ML2, and ML3, may have a low resistance and a high conductivity.

In FIG. 4, the connection electrodes CNE1 and CNE2 and the gate electrode GE having the multi-layer structure, e.g., a three-layer structure, are shown as a representative example, however, the present disclosure should not be limited thereto or thereby. According to some embodiments, the connection electrodes CNE1 and CNE2 and the gate electrode GE may have a multi-layer structure with less or more number of layers than three or may have a single-layer structure.

The connection electrodes CNE1 and CNE2 and the gate electrode GE may be substantially simultaneously formed through the same process. The connection electrodes CNE1 and CNE2 and the gate electrode GE may have the same stack structure as each other. As an example, the connection electrodes CNE1 and CNE2 and the gate electrode GE may have the three-layer structure of Ti/Cu/ITO, however, the present disclosure should not be limited thereto or thereby. As the connection electrodes CNE1 and CNE2 and the gate electrode GE are substantially simultaneously formed through the same process, manufacturing processes of the display panel DP may be simplified.

The first insulating layer INS1 may be located on the gate insulating pattern layer GIL to cover the connection electrodes CNE1 and CNE2 and the gate electrode GE. The second insulating layer INS2 (or an insulating layer) may be located on the first insulating layer INS1. Each of the first insulating layer INS1 and the second insulating layer INS2 may include at least one inorganic layer or an organic layer. The inorganic layer may include at least one of aluminum oxide, titanium oxide, silicon oxide, silicon nitride, silicon oxynitride, zirconium oxide, and hafnium oxide, however, the present disclosure should not be limited thereto or thereby. The organic layer may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the material for the organic layer should not be limited thereto or thereby.

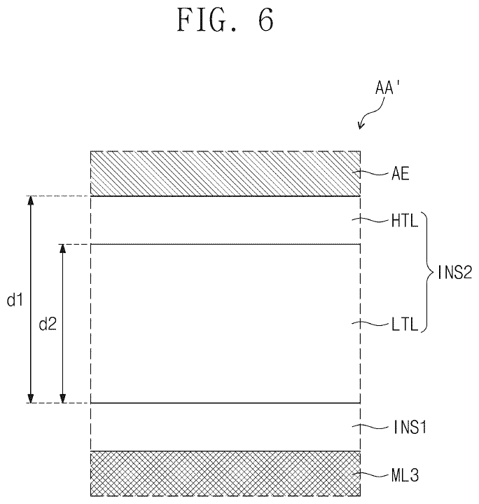

According to some embodiments, at least one of the first insulating layer INS1 and the second insulating layer INS2 may include a low transmittance layer LTL (refer to FIG. 6). As an example, the second insulating layer INS2 may include the low transmittance layer LTL. The low transmittance layer LTL will be described in detail later.

The display element layer DP-OL may be located on the circuit layer DP-CL. The display element layer DP-OL may include a pixel definition layer PDL and the light emitting element OL. As an example, the light emitting element OL may include an organic light emitting element, an inorganic light emitting element, a quantum dot light emitting element, a micro-LED, or a nano-LED, however, the present disclosure should not be limited thereto or thereby. The light emitting element OL may include various embodiments as long as a light is generated or an amount of the light is controlled according to electrical signals.

The pixel definition layer PDL may be located on the second insulating layer INS2 of the circuit layer DP-CL. The pixel definition layer PDL may include a polymer resin. As an example, the pixel definition layer PDL may include a polyacrylate-based resin or a polyimide-based resin. The pixel definition layer PDL may further include an inorganic material in addition to the polymer resin. According to some embodiments, the pixel definition layer PDL may include an inorganic material. As an example, the pixel definition layer PDL may include silicon nitride (SiNₓ), silicon oxide (SiOₓ), or silicon oxynitride (SiOₓN_{y}).

The pixel definition layer PDL may include a light absorbing material. The pixel definition layer PDL may include a black coloring agent. The black coloring agent may include a black pigment or a black dye. The black coloring agent may include a metal material, such as carbon black, chrome, etc., or an oxide thereof. However, the pixel definition layer PDL should not be limited thereto or thereby.

The light emitting element OL may include a first electrode AE, a hole transport region HCL, a light emitting layer EML, an electron transport region ECL, and a second electrode CE, which are sequentially stacked.

The first electrode AE may be located on the second insulating layer INS2 of the circuit layer DP-CL. The first electrode AE may be connected to the first connection electrode CNE1 via a contact hole CHa defined through the first insulating layer INS1 and the second insulating layer INS2. As the first electrode AE is connected to the first connection electrode CNE1, the drain area D-A may be connected to the light emitting element OL through the first connection electrode CNE1.

The pixel definition layer PDL may be provided with a light emitting opening PX-OP defined therethrough to expose at least a portion of the first electrode AE. The portion of the first electrode AE exposed through the light emitting opening PX-OP may correspond to a light-emitting area PXA. The area in which the pixel definition layer PDL is located may correspond to a non-light-emitting area NPXA. The non-light-emitting area NPXA may surround the light-emitting area PXA.

The hole transport region HCL may be located on the first electrode AE. The hole transport region HCL may include at least one of a hole injection layer, a hole transport layer, and an electron block layer. According to some embodiments, the hole transport region HCL may include a plurality of hole transport layers.

The light emitting layer EML may be located on the hole transport region HCL. The light emitting layer EML may have a single-layer structure of a single material, a single-layer structure of different materials, or a multi-layer structure of layers including different materials. According to some embodiments, the light emitting layer EML may generate a blue light as the source light, however, the present disclosure should not be limited thereto or thereby. The display element layer DP-OL may include light emitting elements OL including light emitting layers EML that emit lights having different wavelengths from each other.

The light emitting layer EML may be provided in the form of light emitting pattern to be placed in an area corresponding to the light emitting opening PX-OP, however, the present disclosure should not be limited thereto or thereby. According to some embodiments, the light emitting layer EML may be provided as a common layer that overlaps the light-emitting area PXA and the non-light-emitting area NPXA.

The electron transport region ECL may be located on the light emitting layer EML. The electron transport region ECL may include at least one of a hole block layer, an electron transport layer, and an electron injection layer, however, the present disclosure should not be limited thereto or thereby.

The hole transport region HCL, the light emitting layer EML, and the electron transport region ECL may be formed by various methods, such as a vacuum deposition method, a spin coating method, a cast method, an LB (Langmuir-Blodgett) method, an inkjet printing method, a laser printing method, an LITI (Laser Induced Thermal Imaging) method, etc.

The second electrode CE may be located on the electron transport region ECL. The second electrode CE may be a common electrode. That is, the second electrode CE may be provided as a common layer to overlap the entire area of the light-emitting area PXA and the non-light-emitting area NPXA.

The encapsulation layer TFE may cover the light emitting element OL. The encapsulation layer TFE may encapsulate the display element layer DP-OL. The encapsulation layer TFE may include at least one insulating layer. According to some embodiments, the encapsulation layer TFE may include at least one inorganic layer (hereinafter, referred to as an encapsulation inorganic layer). According to some embodiments, the encapsulation layer TFE may include encapsulation inorganic layers and at least one organic layer (hereinafter, referred to as an encapsulation organic layer) located between the encapsulation inorganic layers.

The encapsulation inorganic layer may protect the display element layer DP-OL from moisture and oxygen, and the encapsulation organic layer may protect the display element layer DP-OL from a foreign substance such as dust particles. The encapsulation inorganic layer may include silicon nitride, silicon oxynitride, silicon oxide, titanium oxide, or aluminum oxide, however, it should not be limited thereto or thereby. The encapsulation organic layer may include an acryl-based compound, an epoxy-based compound, or the like. The encapsulation organic layer may include a photopolymerizable organic material, and it should not be particularly limited.

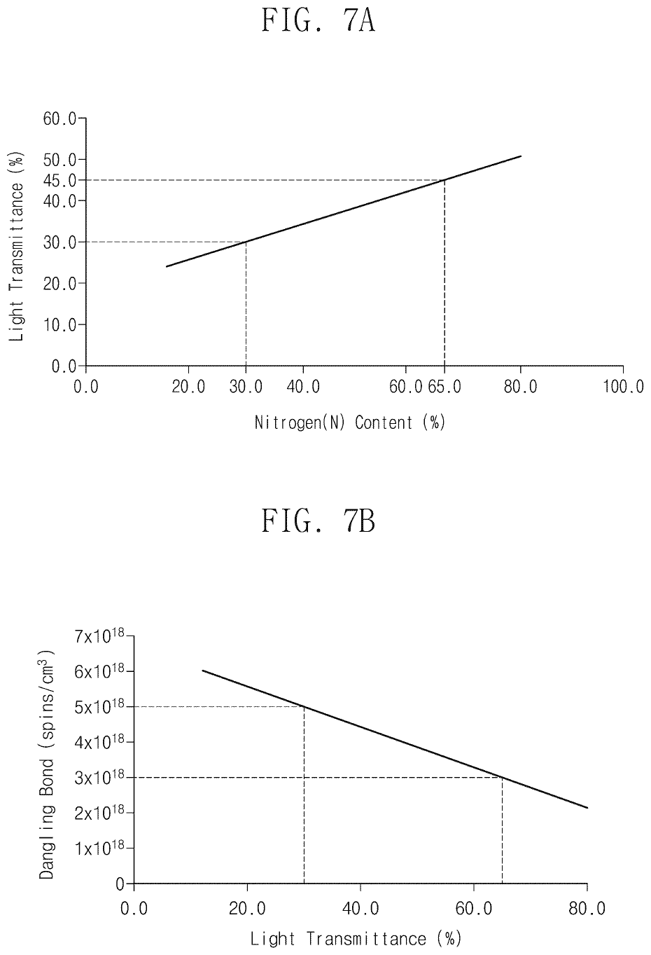

FIG. 6 is an enlarged view of an area AA′ shown in FIG. 4. FIG. 7A is a graph illustrating a relationship between a content of nitrogen atoms contained in a specific material and a light transmittance of the specific material, and FIG. 7B is a graph illustrating a relationship between a light transmittance of a specific material and the number of dangling bonds included in the specific material.

Referring to FIG. 6, the second insulating layer INS2 may include the low transmittance layer LTL and a high transmittance layer HTL. The high transmittance layer HTL may be located on the low transmittance layer LTL.

According to some embodiments, the low transmittance layer LTL may have a light transmittance lower than a light transmittance of the high transmittance layer HTL. The light transmittance of the low transmittance layer LTL may be referred to as a first light transmittance, and the light transmittance of the high transmittance layer HTL may be referred to as a second light transmittance. The first light transmittance may be equal to or greater than 30% (or about 30%) and equal to or smaller than 65% (or about 65%), and the second light transmittance may be equal to or greater than 80% (or about 80%) and equal to or smaller than 95% (or about 95%). The light transmittance is a value that indicates a degree to which a material layer absorbs a light. In detail, the light transmittance is expressed as a value obtained by dividing an intensity of transmitted light from the outside by an intensity of incident light.

The low transmittance layer LTL may include silicon atoms (Si) and nitrogen atoms (N). According to some embodiments, a proportion of the silicon atoms (Si) included in the low transmittance layer LTL may be greater than a proportion of the nitrogen atoms (N) included in the low transmittance layer LTL. As an example, the proportion of the silicon atoms of the low transmittance layer LTL may be equal to or greater than 55% (or about 55%) and equal to or smaller than 70% (or about 70%), and the proportion of the nitrogen atoms of the low transmittance layer LTL may be equal to or greater than 30% (or about 30%) and equal to or smaller than 45% (or about 45%). A ratio of an ammonia (NH3) gas to a silane (SiH4) gas, which are used in a process of forming the low transmittance layer LTL, may be equal to or greater than 0.5:1 (or about 0.5:1) and equal to or smaller than 1.3:1 (or about 1.3:1). That is, a value obtained by dividing a proportion of the ammonia (NH3) gas by a proportion of the silane (SiH4) gas may be equal to or greater than 0.5 (or about 0.5) and equal to or smaller than 1.3 (or about 1.3). As a result, the proportion of the silicon atoms of the low transmittance layer LTL may be equal to or greater than 55% (or about 55%) and equal to or smaller than 70% (or about 70%), and the proportion of the nitrogen atoms of the low transmittance layer LTL may be equal to or greater than 30% (or about 30%) and equal to or smaller than 45% (or about 45%).

The present disclosure should not be limited thereto or thereby, and the low transmittance layer LTL may include an organic material. The organic material may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the organic material should not be limited thereto or thereby.

Referring to FIG. 7A, it is observed that a content ratio of nitrogen atoms of the specific material and the light transmittance of the specific material are directly proportional to each other. That is, as the content ratio of the nitrogen atoms contained in the specific material increases, the light transmittance of the specific material may increase. Referring to FIGS. 6 and 7A, when the proportion of the nitrogen atoms of the low transmittance layer LTL is set to be equal to or greater than 30% (or about 30%) and equal to or smaller than 45% (or about 45%,) the first light transmittance may be equal to or greater than 30% (or about 30%) and equal to or smaller than 65% (or about 65%).

Referring to FIG. 7B, it is observed that the light transmittance of the specific material and the number of dangling bonds included in the specific material are inversely proportional to each other. That is, as the light transmittance of the specific material increases, the number of the dangling bonds in the specific material may gradually decrease. A dangling bond refers to a separated atom from a covalent bond pair, leaving a vacancy where silicon atoms (Si) have not formed bonds and are left unpaired in surface bonding. In the case where the number of the dangling bonds increases, electrons scatter a lot due to the dangling bonds when the electrons flow, making it difficult for the current to flow smoothly. In addition, when the number of the dangling bonds increases, a charge trap may occur, capturing electrons and holes in a corresponding trap area. As a result, electrons or holes trapped in the trap area may be blocked from moving and prevented from being recombined with opposite charges and forming electron/hole pairs.

When the number of the dangling bonds increases in the first insulating layer INS1 or the second insulating layer INS2 shown in FIG. 4 and the charge trap is generated, the electric field may be formed even when the display panel DP is not in operation, and thus, an image retention appeared when the display panel DP is in operation may be visible from the outside. When the number of the dangling bonds is equal to or smaller than 5×10¹⁸ spins/cm³ (or about 5×10¹⁸ spins/cm³), the charge trap may not be generated. Accordingly, the electric field may not be formed when the display panel DP is not in operation, and the image retention appeared when the display panel DP is in operation may not be visible to the outside. In addition, when the light transmittance is equal to or smaller than 65% (or about 65%), deterioration of the transistor TR caused by the external light may be relatively reduced.

Referring to FIGS. 6 to 7B, when the proportion of the nitrogen atoms contained in the low transmittance layer LTL is set to be equal to or greater than about 30% and equal to or smaller than 45% (or about 45%), the first light transmittance may be set to be equal to or greater than 35% (or about 30%) and equal to or smaller than 65% (or about 65%). In addition, when the first light transmittance is set to be equal to or greater than 30% (or about 30%) and equal to or smaller than 65% (or about 65%), the number of the dangling bonds included in the low transmittance layer LTL may be set to be equal to or greater than 3×10¹⁸ spins/cm³ (or about 3×10¹⁸ spins/cm³) and equal to or smaller than 5×10¹⁸ spins/cm³ or about 5×10¹⁸ spins/cm³). That is, the deterioration of the transistor TR caused by the external light may be relatively reduced by the low transmittance layer LTL included in the second insulating layer INS2, and the charge trap may not be generated in the second insulating layer INS2. Accordingly, the image retention appeared when the display panel DP is in operation may not be visible to the outside. As a result, a reliability of the display panel DP may be improved.

According to some embodiments, the low transmittance layer LTL may have a hydrogen emission amount equal to or smaller than 5×10²¹ moles/cm³ (or about 5×10²¹ moles/cm³). As an example, the hydrogen emission amount of the low transmittance layer LTL may be equal to or greater than 1×10²¹ moles/cm³ (or about 1×10²¹ moles/cm³) and equal to or smaller than 5×10²¹ moles/cm³ (or about 5×10²¹ moles/cm³). A hydrogen gas used in a process of forming the low transmittance layer LTL may be set to be greater than 0 sccm (or about 0 sccm) and equal to or smaller than 2000 sccm (or about 2000 sccm), and a reference voltage (a RF power) may be set to be equal to or greater than 8000 W (or about 8000 W) and equal to or smaller than 15000 W (or about 15000 W) to form the low transmittance layer LTL having the hydrogen emission amount equal to or greater than 1×10²¹ moles/cm³ (or about 1×10²¹ moles/cm³) and equal to or smaller than 5×10²¹ moles/cm³ (or about 5×10²¹ moles/cm³). The RF power refers to a power used to generate plasma to form the low transmittance layer LTL.

According to some embodiments, the low transmittance layer LTL may have a thickness d1 equal to or greater than 1500 Å (or about 1500 Å) and equal to or smaller than 3000 Å (or about 3000 Å). As an example, it is preferred that the thickness d1 of the low transmittance layer LTL, which may be required to relatively reduce the deterioration of the transistor TR caused by the external light, is equal to or greater than 2000 Å (or about 2000 Å).

The high transmittance layer HTL may be located between the low transmittance layer LTL and the first electrode AE. The high transmittance layer HTL may protect the transistor TR (refer to FIG. 4) located under the first insulating layer INS1 from moisture and oxygen. The high transmittance layer HTL may include silicon atoms (Si) and nitrogen atoms (N). According to some embodiments, a proportion of the nitrogen atoms in the high transmittance layer HTL may be equal to or greater than 45% (or about 45%). However, embodiments according to the present disclosure are not limited thereto or thereby, and the high transmittance layer HTL may include an organic material. The organic material may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the organic material should not be limited thereto or thereby.

According to the present disclosure, as the proportion of the nitrogen atoms contained in the high transmittance layer HTL is set to be equal to or greater than 45% (or about 45%), the second light transmittance may be set to be equal to or greater than 75% (or about 75%). As an example, the second light transmittance may be equal to or greater than 80% (or about 80%) and equal to or smaller than 95% (or about 95%). As the second light transmittance is set to be equal to or greater than 80% (or about 80%) and equal to or smaller than 95% (or about 95%), the number of the dangling bonds included in the high transmittance layer HTL may be set to be equal to or greater than 1×10¹⁸ spins/cm³ (or about 1×10¹⁸ spins/cm³) and equal to or smaller than 2×10¹⁸ spins/cm³ (or about 2×10¹⁸ spins/cm³).

According to the present disclosure, the high transmittance layer HTL may have a hydrogen emission amount equal to or smaller than 5×10²¹ moles/cm³ (or about 5×10²¹ moles/cm³). As an example, the hydrogen emission amount of the high transmittance layer HTL may be equal to or greater than 1×10²¹ moles/cm³ (or about 1×10²¹ moles/cm³) and equal to or smaller than 5×10²¹ moles/cm³ (or about 5×10²¹ moles/cm³). The second insulating layer INS2 including the low transmittance layer LTL and the high transmittance layer HTL may have a thickness d2 equal to or greater than 2500 Å (or about 2500 Å) and equal to or smaller than 5000 Å (or about 5000 Å).

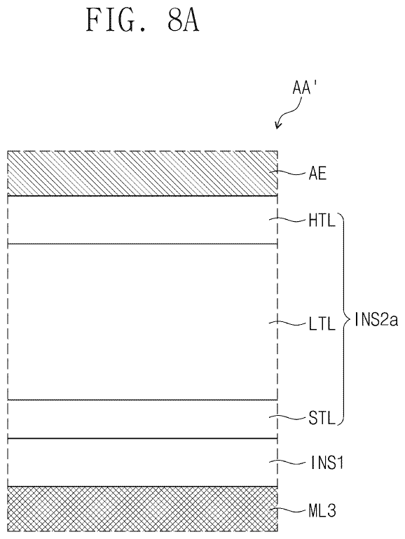

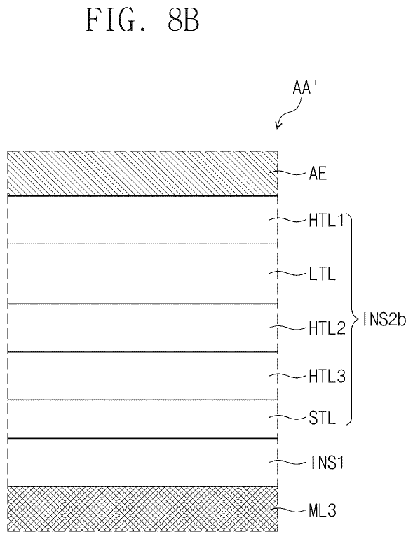

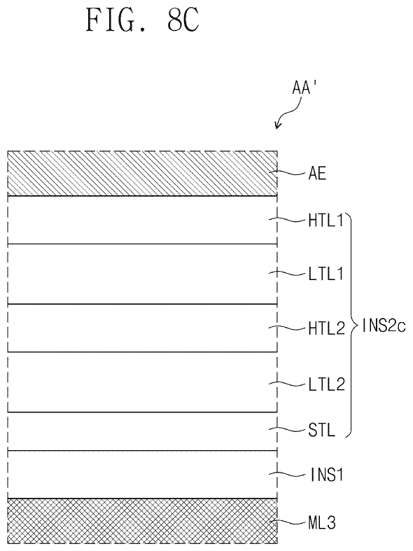

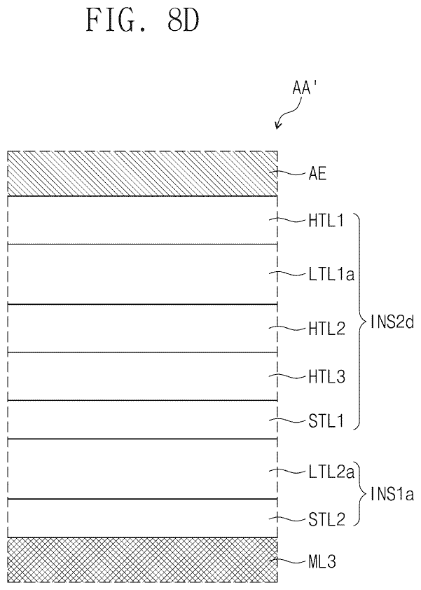

FIGS. 8A to 8D are enlarged views of a portion of a display panel according to some embodiments of the present disclosure. In FIGS. 8A to 8D, the same reference numerals denote the same elements in FIGS. 1 to 6, and thus, detailed descriptions of the same elements will be omitted.

Referring to FIG. 8A, a second insulating layer INS2a may include a stabilizing layer STL, a low transmittance layer LTL, and a high transmittance layer HTL. The low transmittance layer LTL and the high transmittance layer HTL may include substantially the same configuration as the low transmittance layer LTL and the high transmittance layer HTL described with reference to FIG. 6.

The stabilizing layer STL may include silicon atoms (Si), oxygen atoms (O), and nitrogen atoms (N). A proportion of the oxygen atoms of the stabilizing layer STL may be greater than each of a proportion of the silicon atoms of the stabilizing layer STL and a proportion of the nitrogen atoms of the stabilizing layer STL. As an example, the proportion of the oxygen atoms of the stabilizing layer STL may be equal to or greater than 45% (or about 45%) and equal to or smaller than 60% (or about 60%), the proportion of the silicon atoms of the stabilizing layer STL may be equal to or greater than 20% (or about 20%) and equal to or smaller than 35% (or about 35%), and the proportion of the nitrogen atoms of the stabilizing layer STL may be equal to or greater than 10% (or about 10%) and equal to or smaller than 25% (or about 25%). The stabilizing layer STL may be formed through a deposition process such as a chemical vapor deposition process. The stabilizing layer STL may increase an adhesive force between a first insulating layer INS1 and the low transmittance layer LTL.

According to some embodiments, the stabilizing layer STL may have a hydrogen emission amount equal to or smaller than 7×10²¹ moles/cm³ (or about 7×10²¹ moles/cm³). As an example, the hydrogen emission amount of the stabilizing layer STL may be equal to or greater than 5×10²¹ moles/cm³ (or about 5×10²¹ moles/cm³) and equal to or smaller than 7×10²¹ moles/cm³ (or about 7×10²¹ moles/cm³).

Referring to FIG. 8B, a second insulating layer INS2b may include a stabilizing layer STL, a low transmittance layer LTL, and first, second, and third high transmittance layers HTL1, HTL2, and HTL3. The first high transmittance layer HTL1 located on the low transmittance layer LTL may include substantially the same configuration as the high transmittance layer HTL describe with reference to FIG. 6.

The second high transmittance layer HTL2 and the third high transmittance layer HTL3 may be located between the low transmittance layer LTL and the stabilizing layer STL. The second high transmittance layer HTL2 and the third high transmittance layer HTL3 may protect the transistor TR (refer to FIG. 4) located under a first insulating layer INS1 from moisture and oxygen. The second high transmittance layer HTL2 and the third high transmittance layer HTL3 may include silicon atoms (Si) and nitrogen atoms (N). According to some embodiments, a proportion of the nitrogen atoms of each of the second high transmittance layer HTL2 and the third high transmittance layer HTL3 may be equal to or greater than 45% (or about 45%). In detail, the proportion of the nitrogen atoms of the second high transmittance layer HTL2 may be equal to or greater than 45% (or about 45%), and the proportion of the nitrogen atoms of the third high transmittance layer HTL3 may be equal to or greater than 50% (or about 50%). The proportion of the nitrogen atoms of the third high transmittance layer HTL3 may be greater than a proportion of the silicon atoms of the third high transmittance layer HTL3. Each of the second high transmittance layer HTL2 and the third high transmittance layer HTL3 may include an organic material. The organic material may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the organic material should not be limited thereto or thereby.

Referring to FIG. 8C, a second insulating layer INS2c may include a stabilizing layer STL, first and second high transmittance layers HTL1 and HTL2, and first and second low transmittance layers LTL1 and LTL2. The second insulating layer INS2c may include the second low transmittance layer LTL2 instead of the third high transmittance layer HTL3 (refer to FIG. 8B) when compared with the second insulating layer INS2b shown in FIG. 8B.

The second low transmittance layer LTL2 may be located between the stabilizing layer STL and the second high transmittance layer HTL2. The second low transmittance layer LTL2 may include substantially the same configuration as the first low transmittance layer LTL1. Each of the first low transmittance layer LTL1 and the second low transmittance layer LTL2 may include silicon atoms (Si) and nitrogen atoms (N). A proportion of the silicon atoms included in each of the first low transmittance layer LTL1 and the second low transmittance layer LTL2 may be greater than a proportion of the nitrogen atoms (N) included in each of the first low transmittance layer LTL1 and the second low transmittance layer LTL2.

Each of the first low transmittance layer LTL1 and the second low transmittance layer LTL2 may have a first light transmittance. As an example, the first light transmittance may be equal to or greater than 30% (or about 30%) and equal to or smaller than 65% (or about 65%). The number of dangling bonds included in each of the first low transmittance layer LTL1 and the second low transmittance layer LTL2 may be set to be equal to or greater than 3×10¹⁸ spins/cm³ (or about 3×10¹⁸ spins/cm³) and equal to or smaller than 5×10¹⁸ spins/cm³ (or about 5×10¹⁸ spins/cm³). As the second insulating layer INS2c includes the first low transmittance layer LTL1 and the second low transmittance layer LTL2, the deterioration of the transistor TR (refer to FIG. 4) caused by the external light may be relatively reduced. Components included in the second insulating layer INS2c should not be limited to those shown in FIG. 8C, and the second insulating layer INS2c may further include a third low transmittance layer and a third high transmittance layer.

Referring to FIG. 8D, a second insulating layer INS2d may include a first stabilizing layer STL1, a first low transmittance layer LTL1a, and first, second, and third high transmittance layers HTL1, HTL2, and HTL3, and a first insulating layer INS1a may include a second stabilizing layer STL2 and a second low transmittance layer LTL2a. Materials included in the second insulating layer INS2d may be substantially the same as those of the second insulating layer INS2b shown in FIG. 8B.

The second low transmittance layer LTL2a may have a light transmittance equal to or greater than 30% (or about 30%) and equal to or smaller than 65% (or about 65%). The second low transmittance layer LTL2a may include silicon atoms (Si) and nitrogen atoms (N). According to some embodiments, a proportion of the silicon atoms of the second low transmittance layer LTL2a may be greater than a proportion of the nitrogen atoms included in the second low transmittance layer LTL2a. As an example, the proportion of the silicon atoms of the second low transmittance layer LTL2a may be equal to or greater than 55% (or about 55%) and equal to or smaller than 70% (or about 70%), and the proportion of the nitrogen atoms of the second low transmittance layer LTL2a may be equal to or greater than 30% (or about 30%) and equal to or smaller than 45% (or about 45%). The number of dangling bonds included in the second low transmittance layer LTL2a may be equal to or greater than 3×10¹⁸ spins/cm³ (or about 3×10¹⁸ spins/cm³) and equal to or smaller than 5×10¹⁸ spins/cm³ (or about 5×10¹⁸ spins/cm³). Descriptions on the second low transmittance layer LTL2a may be equally applied to the first low transmittance layer LTL1a.

The second stabilizing layer STL2 may include silicon atoms (Si), oxygen atoms (O), and nitrogen atoms (N). According to some embodiments, a proportion of the oxygen atoms of the second stabilizing layer STL2 may be greater than each of a proportion of the silicon atoms of the second stabilizing layer STL2 and a proportion of the nitrogen atoms of the second stabilizing layer STL2. As an example, the proportion of the oxygen atoms of the second stabilizing layer STL2 may be equal to or greater than 45% (or about 45%) and equal to or smaller than 60% (or about 60%), the proportion of the silicon atoms of the second stabilizing layer STL2 may be equal to or greater than 20% (or about 20%) and equal to or smaller than 35% (or about 35%), and the proportion of the nitrogen atoms of the second stabilizing layer STL2 may be equal to or greater than 10% (or about 10%) and equal to or smaller than 25% (or about 25%). The second stabilizing layer STL2 may be formed through a deposition process such as a chemical vapor deposition process. The second stabilizing layer STL2 may increase an adhesive force between a third conductive layer ML3 and the second low transmittance layer LTL2a. Descriptions on the second stabilizing layer STL2 may be equally applied to the first stabilizing layer STL1.

According to some embodiments, as the first insulating layer INS1a includes the second low transmittance layer LTL2a, the deterioration of the transistor TR (refer to FIG. 4) caused by the external light may be relatively reduced. In addition, because the charge trap does not occur in the first insulating layer INS1a, the image retention generated when the display panel DP (refer to FIG. 4) is in operation may not be visible to the outside.

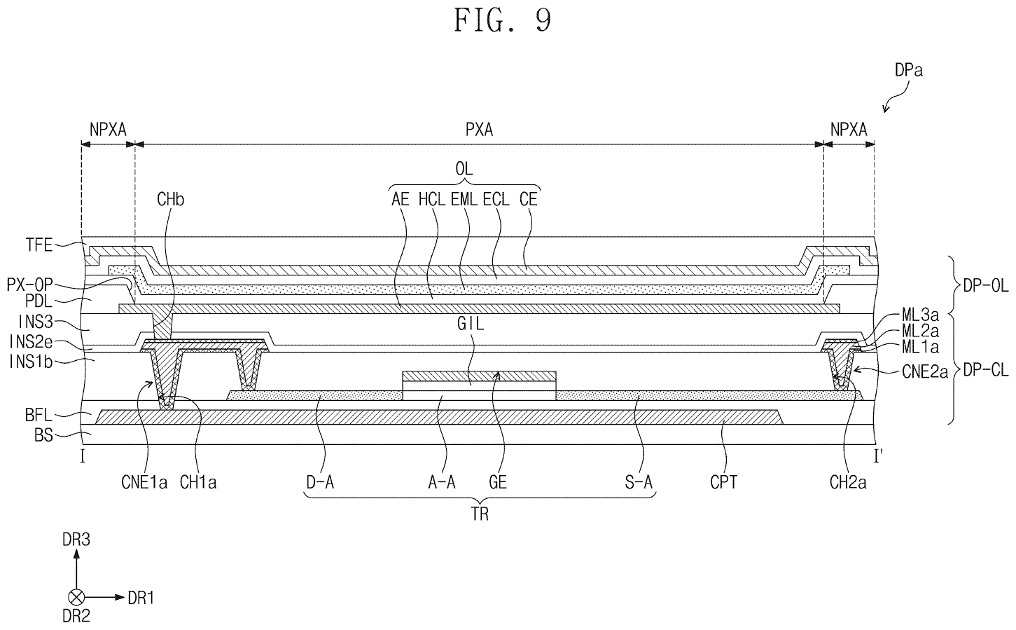

FIG. 9 is a cross-sectional view of a display panel DPa according to some embodiments of the present disclosure.

Referring to FIG. 9, a conductive pattern CPT may be located on a base substrate BS. The conductive pattern CPT may receive a bias voltage. The conductive pattern CPT may receive a first voltage. The conductive pattern CPT may prevent or reduce an electric potential caused by a polarization phenomenon from affecting a transistor TR. The conductive pattern CPT may prevent or reduce instances of an external light reaching the transistor TR. According to some embodiments, the conductive pattern CPT may be a floating electrode isolated from other electrodes or lines. The conductive pattern CPT may be arranged to correspond to the transistor TR. The conductive pattern CPT may include a metal material, e.g., molybdenum.

A first connection electrode CNE1a may be located on a first insulating layer INS1b. The first connection electrode CNE1a may be connected to the conductive pattern CPT via a first contact hole CH1a defined through a buffer layer BFL and the first insulating layer INS1b. In addition, the first connection electrode CNE1a may be in contact with a portion of a drain area D-A and may be connected to the drain area D-A. The drain area D-A and the conductive pattern CPT may be electrically connected to each other via the first connection electrode CNE1a. As the conductive pattern CPT with high conductivity is connected to the drain area D-A, current transfer characteristics may be improved.

A second connection electrode CNE2a may be located on the first insulating layer INS1b. The second connection electrode CNE2a may be connected to a source area S-A via a second contact hole CH2a defined through the first insulating layer INS1b. The second connection electrode CNE2a may be connected to a power line supplying a power to a light emitting element OL and may supply a first voltage to the transistor TR.

Each of the first connection electrode CNE1a and the second connection electrode CNE2a may have a multi-layer structure in which conductive layers ML1a, ML2a, and ML3a including different materials from each other are stacked. The conductive layers ML1a, ML2a, and ML3a may include first, second, and third conductive layers ML1a, ML2a, and ML3a. The first, second, and third conductive layers ML1a, ML2a, and ML3a may be stacked through a sputtering process, however, the present disclosure should not be limited thereto or thereby.

Each of the first, second, and third conductive layers ML1a, ML2a, and ML3a may include a metal material. As an example, each of the first, second, and third conductive layers ML1a, ML2a, and ML3a may include one of molybdenum (Mo), aluminum (AI), chromium (Cr), gold (Au), titanium (Ti), nickel (Ni), neodymium (Nd), copper (Cu), and indium tin oxide (ITO) or an alloy thereof. The first, second, and third conductive layers ML1a, ML2a, and ML3a may include different metal materials from each other. The second conductive layer ML2a may include a metal material with high conductivity, and the first and third conductive layers ML1a and ML3a respectively located under and on the second conductive layer ML2 may include a metal material with a corrosion resistance. As an example, the first conductive layer ML1a may include titanium (Ti), the second conductive layer ML2a may include copper (Cu), and the third conductive layer ML3a may include indium tin oxide (ITO), however, the present disclosure should not be limited thereto or thereby.

A gate electrode GE may be located on a gate insulating pattern layer GIL. The gate electrode GE may overlap an active area A-A when viewed in the plane (or in a plan view) and may be spaced apart from the active area A-A with the gate insulating pattern layer GIL interposed therebetween in the thickness direction.

The connection electrodes CNE1a and CNE2a may be spaced apart from the gate electrode GE when viewed in the plane (or in a plan view). The connection electrodes CNE1a and CNE2a and the gate electrode GE may include different materials from each other. That is, different from the connection electrodes CNE1 and CNE2 and the gate electrode GE shown in FIG. 4, the connection electrodes CNE1a and CNE2a may be formed through a separate process from the gate electrode GE.

A first electrode AE may be located on a third insulating layer INS3 of a circuit layer DP-CL. The first electrode AE may be connected to the first connection electrode CNE1a via a contact hole CHb defined through a second insulating layer INS2e and the third insulating layer INS3. As the first electrode AE is connected to the first connection electrode CNE1a, the drain area D-A may be connected to the light emitting element OL through the first connection electrode CNE1a.

According to the present disclosure, at least one of the first insulating layer INS1b and the second insulating layer INS2e may include the low transmittance layer LTL (refer to FIG. 6). As a result, the deterioration of the transistor TR caused by the external light may be relatively reduced, and because the charge trap does not occur in the first insulating layer INS1b or the second insulating layer INS2e, an image retention generated when the display panel DPa is in operation may not be visible to the outside. Thus, reliability of the display panel DPa may be improved.

Although aspects of some embodiments of the present disclosure have been described, it is understood that embodiments according to the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of embodiments according to the present disclosure shall be determined according to the attached claims, and their equivalents.

What is claimed is:

1. A display device comprising:
a base substrate;
a transistor on the base substrate and comprising a semiconductor pattern and a gate electrode;
a gate insulating pattern layer on the semiconductor pattern;
connection electrodes on the gate insulating pattern layer and connected to the semiconductor pattern via contact holes; and
an insulating layer on the connection electrodes and the transistor, wherein the connection electrodes are on a same layer as the gate electrode, the insulating layer comprises a low transmittance layer having a light transmittance equal to or greater than 30% and equal to or smaller than 65%.

2. The display device of claim 1, wherein the low transmittance layer comprises silicon atoms and nitrogen atoms, and a proportion of the silicon atoms of the low transmittance layer is greater than a proportion of the nitrogen atoms of the low transmittance layer.

3. The display device of claim 2, wherein the proportion of the silicon atoms of the low transmittance layer is equal to or greater than 55% and equal to or smaller than 70%, and the proportion of the nitrogen atoms of the low transmittance layer is equal to or greater than 30% and equal to or smaller than 45%.

4. The display device of claim 1, wherein the low transmittance layer has a thickness equal to or greater than 1500 angstroms and equal to or smaller than 3000 angstroms.

5. The display device of claim 1, wherein the insulating layer further comprises a first high transmittance layer on the low transmittance layer, and the first high transmittance layer has a light transmittance equal to or greater than 80% and equal to or smaller than 95%.

6. The display device of claim 5, wherein the first high transmittance layer comprises silicon atoms and nitrogen atoms, and a proportion of the nitrogen atoms of the first high transmittance layer is greater than a proportion of the silicon atoms of the first high transmittance layer.

7. The display device of claim 5, wherein the insulating layer further comprises a second high transmittance layer under the low transmittance layer, and the second high transmittance layer has a light transmittance equal to or greater than 80% and equal to or smaller than 95%.

8. The display device of claim 7, wherein the insulating layer further comprises a stabilizing layer under the second high transmittance layer, the stabilizing layer comprises silicon atoms, nitrogen atoms, and oxygen atoms, and a proportion of the oxygen atoms of the stabilizing layer is greater than each of a proportion of the silicon atoms of the stabilizing layer and a proportion of the nitrogen atoms of the stabilizing layer.

9. The display device of claim 8, wherein the insulating layer further comprises a third high transmittance layer between the second high transmittance layer and the stabilizing layer, and the third high transmittance layer has a light transmittance equal to or greater than 80% and equal to or smaller than 95%.

10. The display device of claim 9, wherein the insulating layer has a thickness equal to or greater than 2500 angstroms and equal to or smaller than 5000 angstroms.

11. The display device of claim 1, wherein the semiconductor pattern comprises a source area, a drain area, and an active area, the connection electrodes comprise:
a first connection electrode connected to the drain area; and
a second connection electrode connected to the source area, and the first connection electrode and the second connection electrode are on a same layer as the gate electrode.

12. The display device of claim 11, wherein the first connection electrode and the second connection electrode comprise a same material as the gate electrode.

13. The display device of claim 11, further comprising first and second conductive patterns between the base substrate and the transistor and spaced apart from each other in a plan view, wherein the first conductive pattern is electrically connected to the drain area through the first connection electrode, and the second conductive pattern is electrically connected to the source area through the second connection electrode.

14. The display device of claim 13, wherein the gate insulating pattern layer comprises first, second, and third insulating patterns, the first insulating pattern overlaps the first connection electrode, the second insulating pattern overlaps the gate electrode, and the third insulating pattern overlaps the second connection electrode.

15. The display device of claim 14, wherein the first connection electrode is connected to the first conductive pattern via a first contact hole defined through the first insulating pattern, and the second connection electrode is connected to the second conductive pattern via a second contact hole defined through the third insulating pattern.

16. The display device of claim 11, further comprising a light emitting element on the first and second connection electrodes and comprising a first electrode, a light emitting layer, and a second electrode, wherein the first electrode is electrically connected to the transistor through the first connection electrode.

17. A display device comprising:
a base substrate;
a transistor on the base substrate and comprising a semiconductor pattern and a gate electrode;
a gate insulating pattern layer on the semiconductor pattern;
connection electrodes on the gate insulating pattern layer and connected to the semiconductor pattern via contact holes; and
an insulating layer on the connection electrodes and the transistor, the insulating layer comprising:
a low transmittance layer having a first light transmittance; and
a high transmittance layer having a second light transmittance greater than the first light transmittance and on or under the low transmittance layer.

18. The display device of claim 17, wherein the first light transmittance is equal to or greater than 30% and equal to or smaller than 65%, and the second light transmittance is equal to or greater than 80% and equal to or smaller than 95%.

19. The display device of claim 17, wherein the high transmittance layer comprises:
a first high transmittance layer on the low transmittance layer; and
a second high transmittance layer under the low transmittance layer, and each of the first and second high transmittance layers has the second light transmittance.

20. The display device of claim 19, wherein the insulating layer further comprises:
a third high transmittance layer under the second high transmittance layer; and
a stabilizing layer under the third high transmittance layer.

21. The display device of claim 20, wherein the insulating layer has a thickness equal to or greater than 2500 angstroms and equal to or smaller than 5000 angstroms.

22. The display device of claim 17, wherein the low transmittance layer comprises silicon atoms and nitrogen atoms, and a proportion of the silicon atoms of the low transmittance layer is greater than a proportion of the nitrogen atoms of the low transmittance layer.

23. The display device of claim 22, wherein the proportion of the silicon atoms of the low transmittance layer is equal to or greater than 55% and equal to or smaller than 70%, and the proportion of the nitrogen atoms of the low transmittance layer is equal to or greater than 30% and equal to or smaller than 45%.

24. The display device of claim 17, wherein the low transmittance layer has a thickness equal to or greater than 1500 angstroms and equal to or smaller than 3000 angstroms.
